(19) United States
(12) Patent Application Publication
(10) Pub. No.: US 2007/0246193 A1
(43) Pub. Date: Oct. 25, 2007

(54) Orientation insensitive thermosiphon of v-configuration

(76) Inventors: Mohinder Singh Bhatti, Amherst, NY (US); Ilya Reyzin, Williamsville, NY (US); Shrikant Mukund Joshi, Williamsville, NY (US); John Lawrence Pawlak III, Orchard Park, NY (US)

Correspondence Address: DELPHI TECHNOLOGIES, INC., M/C 480-410-202, PO BOX 5052, TROY, MI, 48007, US

(21) Appl. No.: 11/407,636

(22) Filed: Apr. 20, 2006

(51) Int. Cl. H05K 7/20; F28F 19/00

(52) U.S. Cl. 165/104.21; 165/104.33; 257/715; 361/700

(57) ABSTRACT

The invention provides a heat exchanger assembly for cooling an electronic device wherein the upper portion of the housing includes a plurality of condensing tubes extending upwardly from the lower portion of the housing. A plurality of air heat transfer fins zigzag transversely to a primary axis (A) between adjacent ones of the condensing tubes for dissipating heat from vapor boiled off of the refrigerant. At least two next adjacent condensing tubes of the plurality diverge upwardly from the bottom ends toward the top distal ends thereof. Accordingly, the space containing the air heat transfer fins between the two next adjacent condensing tubes is greater at the top distal ends than at the bottom ends of the condensing tubes. The condensing tubes can either have a constant cross-section with diverging tube axes or can have a decreasing cross-section from bottom to top with parallel tube axes.

### BACKGROUND OF THE INVENTION

1. Field of the Invention

The subject invention relates to a heat exchanger assembly for cooling an electronic device.

2. Description of the Prior Art

The operating speed of computers is constantly being improved to create faster computers. With this, comes an increase in heat generation and a need to effectively dissipate that heat.

Heat exchangers and heat sink assemblies have been used that apply natural or forced convection cooling methods to dissipate heat from electronic devices that are highly concentrated heat sources such as microprocessors and computer chips; however, air has a relatively low heat capacity. Thus, liquid-cooled units called LCUs employing a cold plate in conjunction with high heat capacity fluids have been used to remove heat from these types of heat sources. Although LCUs are satisfactory for moderate heat flux, increasing computing speeds have required more effective heat sink assemblies.

Accordingly, thermosiphon cooling units (TCUs) have been used for cooling electronic devices having a high heat flux. A typical TCU absorbs heat generated by the electronic device by vaporizing a working fluid housed on the boiler plate of the unit. The boiling of the working fluid constitutes a phase change from liquid-to-vapor state and as such the working fluid of the TCU is considered to be a two-phase fluid. Vapor generated during boiling of the working fluid is then transferred to a condenser, where it is liquefied by the process of film condensation over the condensing surface of the TCU. The heat is rejected into ambient air flowing over the condenser and fins are commonly employed on the condenser to increase the heat transferred from the vapor. The condensed liquid is returned back to the boiler plate by gravity to continue the boiling-condensing cycle.

Examples of such thermosiphons include PCT Patent Application WO 02/081996A2 to Joshi et al. and U.S. Pat. No. 6,085,831 to DiGiacomo et al.

The Joshi patent discloses an assembly for cooling an electronic device including a housing having a lower portion holding a refrigerant and an upper portion having condensing tubes extending upwardly from the lower portion of the housing. Air heat transfer fins extend between adjacent condensing tubes. The condensing tubes extend parallel to one another and thus, the air fins between two adjacent condensing tubes are of equal length.

The DiGiacomo patent is a thermosiphon including a housing having a lower portion for holding a refrigerant and an upper portion including a plurality of condensing tubes extending upwardly and outwardly along a single vertical plane from the lower portion of the housing. Boiler heat transfer fins extend into the upper portion of the housing to enhance heat transfer from the vapor boiled off of the refrigerant to the upper portion of the housing. The condensing tubes are formed out of a condensing chamber having plate-like fins extending into the chamber from the upper portion of the housing.

Although the prior art effectively dissipates heat from electronic devices, there is a continuing need for alternative designs for effectively dissipating heat from electronic devices. Specifically, there is a need for alternative designs for orientation insensitive thermosiphons.

### SUMMARY OF THE INVENTION AND ADVANTAGES

The invention provides a heat exchanger assembly for cooling an electronic device comprising a housing. The housing includes an upper portion and a lower portion extending along a primary axis wherein the upper portion of the housing includes a plurality of condensing tubes spaced from one another transversely to the axis. The condensing tubes extend axially with each condensing tube extending upwardly from a bottom end at the lower portion of the housing to distal and spaced top ends. A refrigerant is disposed in the lower portion of the housing for undergoing a liquid-to-vapor-to-condensate cycle within the housing. A plurality of air heat transfer fins zigzag transversely to the axis between adjacent ones of the condensing tubes for dissipating heat from the condensing tubes while vapor is boiled off of the refrigerant. At least two next adjacent condensing tubes of the plurality diverge upwardly from the bottom ends toward the distal ends thereof. Accordingly, the space containing the air heat transfer fins between the two next adjacent condensing tubes is greater at the top distal ends than at the bottom ends of the condensing tubes.

The invention provides an alternative design for a compact heat exchanger for cooling an electronic device able to operate in a vertical position, a horizontal position or at any angle of tilt therebetween. The invention provides a constant cross section such that it can be manufactured by extrusion methods thereby lower the cost of manufacturing.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a perspective view in cross-section of the first embodiment of the present invention; and

FIG. 2 is a perspective view in cross-section of the second embodiment of the present invention.

### DETAILED DESCRIPTION OF THE INVENTION

Referring to the Figures, wherein like numerals indicate corresponding parts throughout the several views, a heat exchanger assembly 20 is generally shown for cooling an electronic device 22.

The assembly 20 includes a housing 24 generally indicated having an upper portion 26 and a lower portion 28 extending along a primary axis A, and having a front end 30 and a back end 32. The lower portion 28 of the housing 24 includes a floor 34, a top wall 36, and diverging side walls 38 extending outwardly and upwardly from the floor 34 to the top wall 36. The upper portion 26 of the housing 24 includes a plurality of condensing tubes 40, 42 extending axially and spaced from one another transversely to the axis. Each condensing tube extends upwardly from a bottom end 44 at the lower portion 28 of the housing 24 to distal and spaced top ends 46.

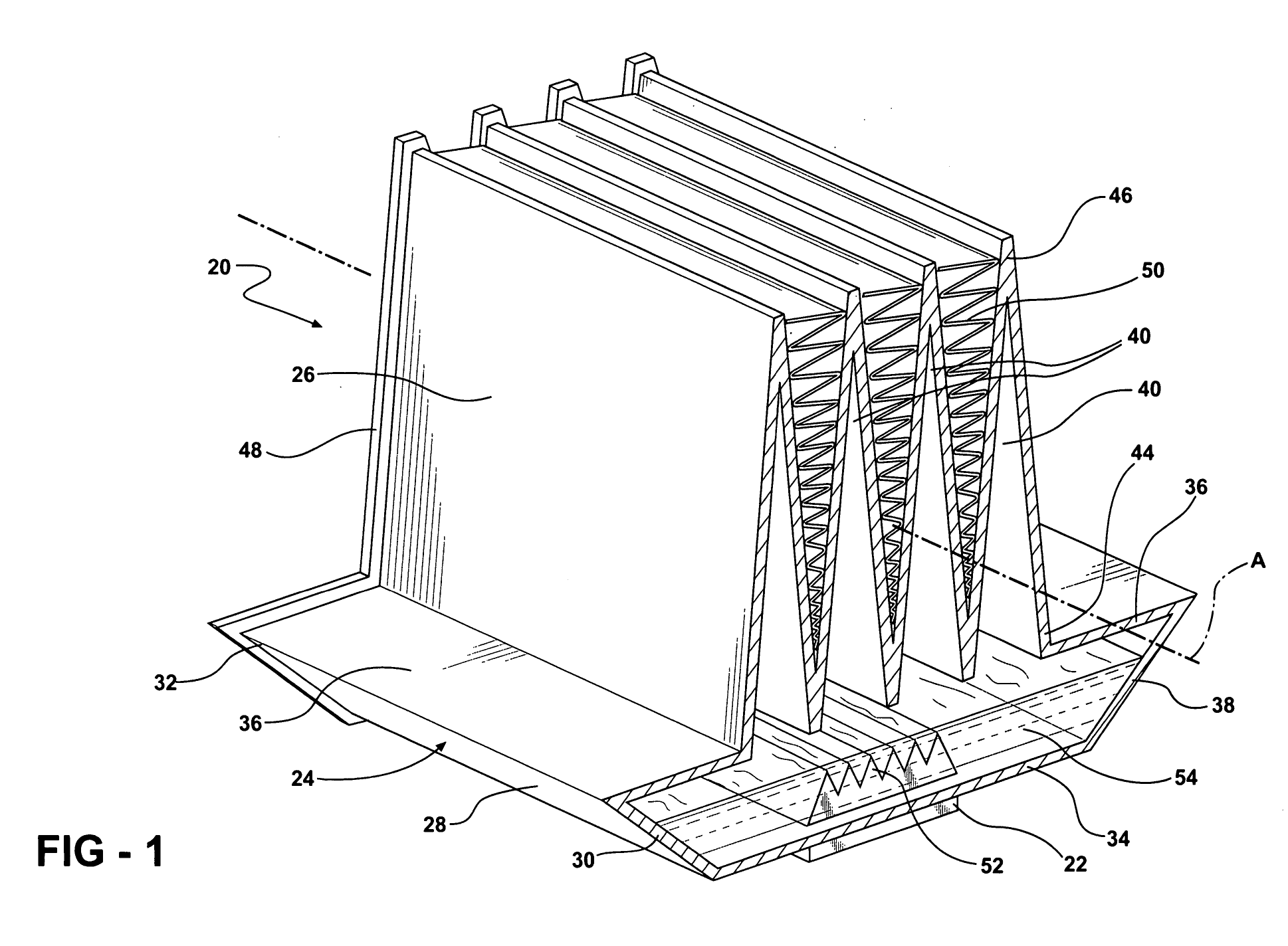

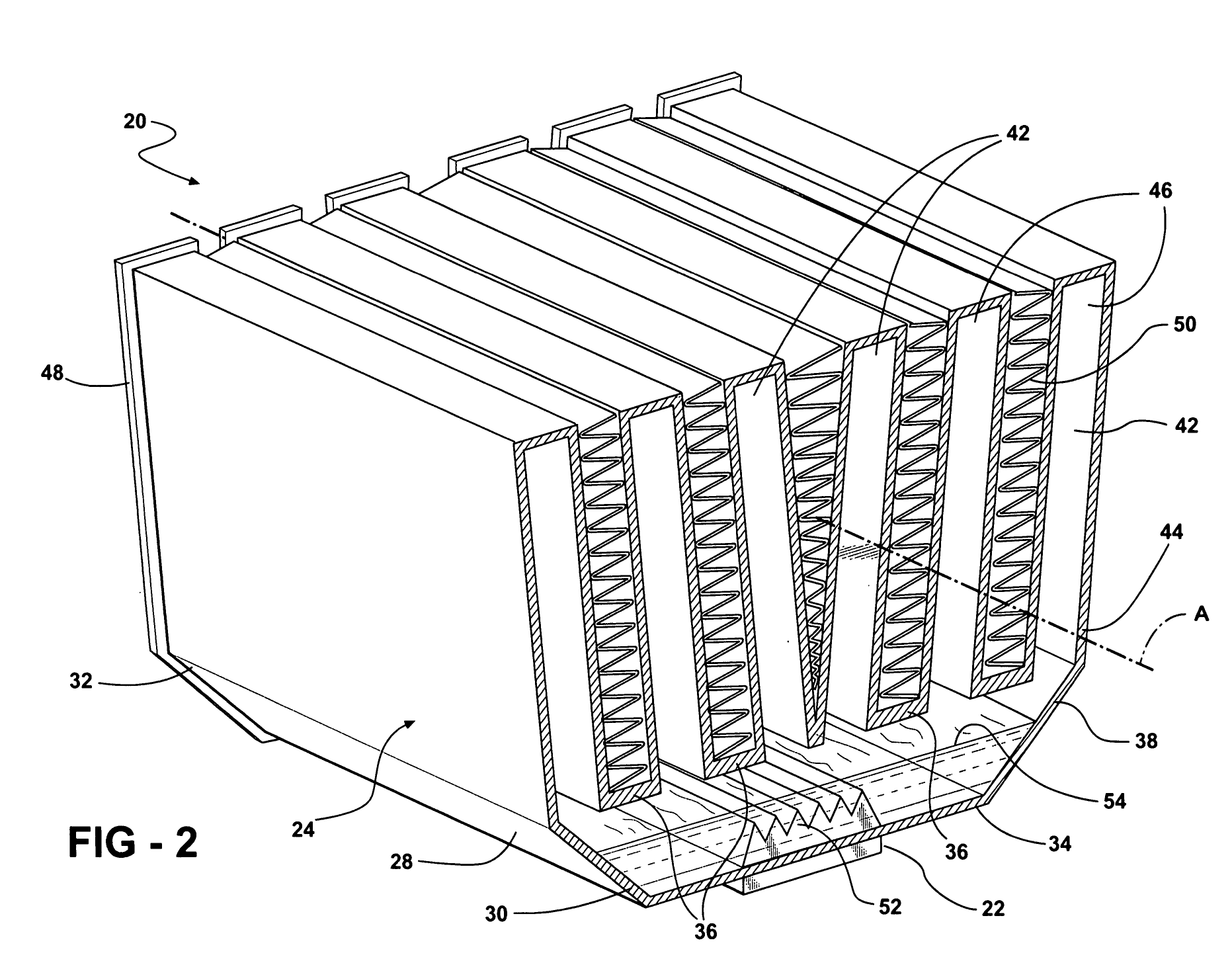

In the embodiment shown in FIG. 1, the top wall 36 extends from the side walls 38 horizontally and inwardly to the upper portion 26 of the housing 24. In other words, the top wall 36 extends from outer most ones of the condensing tubes 40 to the side walls 38. In the embodiment of FIG. 2, the top wall 36 extends between adjacent condensing tubes 42.

A pair of endplates 48 is secured to the housing 24 wherein one endplate 48 is disposed on the front end 30 and the other endplate 48 is disposed on the back end 32. The endplates 48 are thin plates that are brazed and cover the cross section of the housing 24 that includes all of the condensing tubes 40, 42 and the lower portion 28 of the housing 24 between the planes of the endplates 48. The endplates 48 do not cover the spaces between adjacent condensing tubes 40, 42 wherein the fins 50, 52 are disposed, so that air can be moved through the spaces and over the air fins 50.

A refrigerant 54 is disposed in the lower portion 28 of the housing 24 for undergoing a liquid-to-vapor-to-condensate cycle within the housing 24. A plurality of boiler heat transfer fins 52 are disposed in the lower portion 28 for transferring heat from the electronic device 22 to the refrigerant 54. The boiler heat transfer fins 52 extend axially along the floor 34 of the lower portion 28 of the housing 24.

The housing 24 and the boiler heat transfer fins 52 disposed in the lower portion 28 of the housing 24 are extruded and thereafter cut into sections of a predetermined length. The endplates 48 are subsequently secured to the front end 30 and back end 32 of the housing 24 thereby lowering the cost of manufacturing the invention as compared to conventional methods of manufacturing.

A plurality of air heat transfer fins 50 are included and zigzag transversely to the primary axis A between adjacent ones of the condensing tubes 40, 42 for dissipating heat from the condensing tubes 40, 42 as vapor is boiled off of the refrigerant 54. The air heat transfer fins 50 extend axially along the entire length of the condensing tubes 40, 42 between opposite ends thereof.

The assembly 20 is distinguished by at least two next adjacent condensing tubes 40, 42 of the plurality diverging upwardly from the bottom ends 44 toward the distal ends 46 thereof. The two next adjacent condensing tubes 40, 42 are the center two of the plurality. The air heat transfer fins 50 extend between the two next adjacent condensing tubes 40, 42 and the space between the two next adjacent condensing tubes 40, 42 is greater at the top distal ends 46 than at the bottom ends 44 of the condensing tubes 40, 42, i.e., the space containing the air fins 50. As illustrated in both embodiments, the air fins 50 zigzag between evenly spaced fin apexes from top to bottom between the condensing tubes 40, 42. Alternatively, the air fins 50 that zigzag between apexes can be stretched to vary the distance vertically between apexes so that the air fins 50 are denser at the top of the diverging condensing tubes 40, 42.

In the embodiment shown in FIG. 1, each of the condensing tubes 40 has a decreasing cross section between the bottom end 44 and the top end 46 forming a triangular point at each distal end 46. By having the condensing tubes 40 form a triangle, when the invention is rotated into a horizontal position, the bottom wall of each condensing tube 40 will be slanted to facilitate drainage of the condensate refrigerant 54 back into the lower portion 28 of the housing 24. The cross-section of each condensing tube 40 is preferably rectangular, such that the assembly 20 may be manufactured by extrusion methods.

The two next adjacent condensing tubes 40 extend vertically along parallel tube axes and at least one of the remaining condensing tubes 40 (all of them as illustrated) extends along a tube axis parallel to each of the tube axes of the two next adjacent condensing tubes 40. FIG. 1 shows the two next adjacent condensing tubes 40 with two condensing tubes 40 extending parallel to each of the two next adjacent condensing tubes 40.

In the embodiment shown in FIG. 2, each of the condensing tubes 42 has a constant cross section between the bottom end 44 to the top end 46. The cross-section is preferably rectangular, so that the assembly 20 may be manufactured by extrusion methods. The two next adjacent condensing tubes 42 diverge from one another and the adjacent condensing tubes 42 extend along diverging tube axes. At least one of the remaining condensing tubes 42 extends parallel to each of the tube axes of the two next adjacent condensing tubes 42 whereby the condensing tubes 42 fan outwardly from the lower portion 28 of the housing 24 extending transversely to the primary axis A so that the assembly 20 is operational in numerous orientations.

FIG. 2 shows two such condensing tubes 42 on each side of the two next adjacent condensing tubes 42 wherein both pairs extend along parallel tube axes. When the embodiment in FIG. 2 is rotated into a horizontal position, the upward facing condensing tubes 42 would have slanted walls to facilitate drainage of the condenses refrigerant 54 back into the lower portion 28 of the housing 24.

In operation, the electronic device 22 generates heat which is transferred to the boiler heat transfer fins 52, causing the refrigerant 54 to boil. Vapor boiled off of the refrigerant 54 then rises due to gravity into the condensing tubes 40, 42. In a vertical position, shown in FIGS. 1 and 2, the vapor rises into all of the condensing tubes 40, 42. If the embodiment shown in FIG. 1 is tilted into a horizontal position, the vapor will travel in a space in the lower portion 28 of the housing 24 surrounded by the side wall 38 and the top wall 36 thereby providing a condensing chamber. If the embodiment shown in FIG. 2 is tilted from the vertical position down to the horizontal position, the vapor will only travel into the condensing tubes 40 extending upwardly in that position. As the vapor rises into the condensing tubes 40, 42, heat is transferred from the vapor into the condensing tubes 40, 42. Thereafter the heat is dissipated from the air fins 50 into ambient air flowing over the air fins 50. The condensate then travels by gravity back into the lower portion 28 of the housing 24 where the liquid refrigerant 54 is housed to continue the boiling-condensing cycle.

Obviously, many modifications and variations of the present invention are possible in light of the above teachings. The invention may be practiced otherwise than as specifically described within the scope of the appended claims.

What is claimed is:

1. A heat exchanger assembly for cooling an electronic device comprising;
a housing having an upper portion and a lower portion extending along a primary axis (A) between a front end and a back end,
a refrigerant disposed in said lower portion of said housing for undergoing a liquid-to-vapor-to-condensate cycle within said housing,
said upper portion of said housing including a plurality of condensing tubes spaced from one another transversely to said primary axis (A) and extending axially with each of said condensing tubes extending upwardly from a bottom end at said lower portion of said housing to distal and spaced top ends,
a plurality of air heat transfer fins zigzagging transversely to said primary axis (A) between adjacent ones of said condensing tubes for dissipating heat from said condensing tubes while vapor is boiled off of said refrigerant, and
at least two next adjacent condensing tubes of said plurality diverging from one another upwardly from said bottom ends toward said distal ends thereof with the space containing said air heat transfer fins between said two next adjacent condensing tubes being greater at said top distal ends than at said bottom ends of said condensing tubes.

2. An assembly as set forth in claim 1 wherein each of said condensing tubes has a constant cross section between said bottom end and said top end and said two next adjacent condensing tubes extend along diverging tube axes.

3. An assembly as set forth in claim 2 wherein at least one of the remaining condensing tubes extends along a tube axis parallel to each of said tube axes of said two next adjacent condensing tubes.

4. An assembly as set forth in claim 1 wherein each of said condensing tubes has a decreasing cross section between said bottom end and said top end and said two next adjacent condensing tubes extend along parallel tube axes.

5. An assembly as set forth in claim 4 wherein at least one of the remaining condensing tubes extends along a tube axis parallel to each of said tube axes of said two next adjacent condensing tubes.

6. An assembly as set forth in claim 1 wherein said housing includes two endplates disposed on said housing for closing said condensing tubes and said lower portion wherein one endplate is disposed on said front end of said housing and one endplate is disposed on said back end of said housing and said primary axis (A) extends between said endplates.

7. An assembly as set forth in claim 6 including a fan assembly supported on said endplate on said back end of said housing for moving air axially over said air heat transfer fins.

8. An assembly as set forth in claim 1 wherein said lower portion of said housing includes a floor and a top wall and side walls extending outwardly and upwardly from said floor.

9. An assembly as set forth in claim 1 wherein said lower portion of said housing includes a floor and a top wall and side walls extending outwardly and upwardly from said floor to said top wall and wherein said top wall of said housing extends from outer most ones of said condensing tubes to said side walls.

10. An assembly as set forth in claim 1 wherein said air heat transfer fins extend axially along an entire length of said condensing tubes.

11. An assembly as set forth in claim 1 including a plurality of boiler heat transfer fins disposed in said lower portion for transferring heat from the electronic device to said refrigerant.

12. An assembly as set forth in claim 11 wherein said boiler heat transfer fins extend axially.

13. A heat exchanger assembly for cooling an electronic device comprising;
a housing having an upper portion and a lower portion extending along a primary axis (A) between a front end and a back end,
said lower portion of said housing including a floor and a top wall and side walls extending outwardly and upwardly from said floor,
said upper portion of said housing including a plurality of condensing tubes spaced from one another transversely to said primary axis (A) and extending axially with each condensing tube extending upwardly from a bottom end at said top wall of said lower portion of said housing to distal and spaced top ends,
two endplates disposed on said housing for closing said condensing tubes and said lower portion wherein one endplate is disposed on said front end of said housing and one endplate is disposed on said back end of said housing and said primary axis (A) extends between said endplates,
a refrigerant disposed in said lower portion of said housing for undergoing a liquid-to-vapor-to-condensate cycle within said housing,
a plurality of boiler heat transfer fins disposed in said lower portion and extending axially for transferring heat from the electronic device to said refrigerant,
a plurality of air heat transfer fins zigzagging transversely to said primary axis (A) between adjacent ones of said condensing tubes and extending axially along an entire length of said condensing tubes for dissipating heat from said condensing tubes while vapor is boiled off of said refrigerant,
a fan assembly supported adjacent said endplate on said back end of said housing for moving air axially over said air heat transfer fins, and
at least two next adjacent condensing tubes of said plurality diverging from one another upwardly from said bottom ends toward said distal top ends thereof with the space containing said air heat transfer fins between said two next adjacent condensing tubes being greater at said distal ends than at said bottom ends of said condensing tubes.

14. An assembly as set forth in claim 13 wherein each of said condensing tubes has a constant cross section between said bottom end to said top end and said two next adjacent condensing tubes extend along diverging tube axes.

15. An assembly as set forth in claim 14 wherein at least one of the remaining condensing tubes extend along a tube axis parallel to each of said two next adjacent condensing tubes.

16. An assembly as set forth in claim 13 wherein each of said condensing tubes has a decreasing cross section between said bottom end and said top end and said two next adjacent condensing tubes extend along parallel tube axes.

17. An assembly as set forth in claim 16 wherein said lower portion of said housing includes a floor and a top wall and side walls extending outwardly and upwardly from said floor to said top wall and wherein said top wall of said housing extends from outer most ones of said condensing tubes to said side walls.
